(19) United States
(12) Patent Application Publication
(10) Pub. No.: US 2011/0240091 A1
(43) Pub. Date: Oct. 6, 2011

(54) Method for Attaching Flat Electronic Components Onto a Flexible Surface Structure

(75) Inventors: Ulrich Forster, St. Gallen (CH); Jan-Helge Zimmermann, Zurich (CH)

(73) Assignee: FORSTER ROHNER AG, St. Gallen (CH)

(21) Appl. No.: 13/133,116

(22) PCT Filed: Dec. 1, 2009
(86) PCT No.: PCT/EP2009/066114

§ 371 Date: Jun. 6, 2011

(30) Foreign Application Priority Data
Dec. 4, 2008 (CH) 01897/08

(51) Int. Cl. H01L 31/042; D05B 23/00; D05C 5/02; H05K 13/00; B32B 37/12; B05D 5/06; B05D 1/02; B05D 1/28

(52) U.S. Cl. 136/244; 112/475.18; 112/475.19; 156/91; 427/58

(57) ABSTRACT

The invention relates to a method for attaching a flat electronic component (2, 2a; 12; 22; 32; 42), in particular a photovoltaic cell, onto a flexible surface structure (1; 11; 21; 31), to the use of a programmable embroidering machine, to a flexible surface structure (1; 11; 21; 31; 41) comprising at least one electronic component (2, 2a; 12; 22; 32; 42) and to a solar module. At least one conduction path (4, 5; 14, 15; 24, 25; 34, 35; 44, 45) is embroidered onto the flexible surface structure, wherein a first conduction path (4; 14; 24; 34; 44) only contacts a first surface segment, in particular the bottom side (16; 36; 46), of the component (2, 2a; 12; 22; 32; 42) and a second conduction path (5; 15; 25; 35; 45) only contacts a second surface segment, in particular the top side (7; 17), of the same component (2, 2a; 12; 22; 32; 42).

The invention relates to a method for attaching flat electronic components, in particular photovoltaic cells, onto a flexible surface structure, to the use of a program-controlled embroidering machine, to a flexible surface structure with at least one electronic component and to a solar module.

Both in the private sector and in the commercial sector, there is a demand for electronic circuits that can be flexibly arranged. Thus, it is desirable that electronic components, such as sensors, antennas, power sources and solar cells, are miniaturized and used by being attached to garments, bags, high pitched roofs, furnishing fabrics, etc.

It is known, for example, from EP 0 379 961, US 2007/0151593 or DE 44 36 246 to attach solar modules onto flexible surface structures, such as garments. The solar cells are in this case already arranged and interconnected in modules in a conventional way. The solar cells are thereby generally provided with an appropriate interconnection and are combined into modules. They form a flat, rather stiff unit, which is adhesively attached, sewn or embroidered onto the material provided with them. To be able to generate a sufficient amount of power, the solar modules must be of a certain size, and consequently require a corresponding surface area. The modules can then no longer be attached anywhere, and the textile surface structure loses its flexibility. It can no longer be folded together or rolled up small or is not very comfortable for the wearer.

Furthermore, it is known, for example from DE 10 2006 027 213, in particular for so-called “smart textiles”, from EP 1923 680 and from WO 2006/108310, to form electrically conductive textile structures, for example to sew or embroider conductive tracks. With these conductive tracks, electronic components can indeed be connected in an electrically conducting manner or hooked up to an energy supply. However, more complex circuits, as are necessary for example for producing a solar module, are not realized.

There is therefore the object of avoiding the disadvantages of the known art and, in particular, providing a flexible surface structure which is provided with interconnected electronic components and at the same time largely retains its flexibility.

The object is achieved by a method for attaching at least one flat electronic component, in particular a photovoltaic cell, onto a flexible surface structure with the features of claim 1.

The flexible surface structure consists of embroiderable material, such as textiles, knitted or woven fabrics, leather, nonwovens, films and other technical surface structures.

To establish electrically conducting contact for the at least one flat electronic component applied to the flexible surface structure, firstly at least one conductive track is applied. This conductive track establishes electrically conducting contact with the underside of the at least one electronic component, and then at least one further conductive track is applied.

The further conductive track establishes electrically conducting contact with a second surface segment, in particular the upper side, of the at least one electronic component. The conductive tracks may be adhesively attached or applied in some other way. At least one conductive track is embroidered on.

The embroidering on takes place by a program-controlled embroidering technique, in particular by means of a shuttle embroidering machine.

The underside of the electronic component is understood as meaning the side of the component that is facing the flexible surface structure; the upper side is understood as meaning the side facing away from the flexible surface structure.

As a result, contact is established on the respectively outer layers of components that are made up in particular of semiconductor layers, for example the p and n layers of a photovoltaic or solar cell.

The electrically conducting contact is preferably established by the conductive track lying taut against the electronic component. For this purpose, the component is advantageously applied to the surface structure after the first conductive track and before the second conductive track is embroidered. During application, it is ensured that the component is secured in its position and can no longer slip.

As an alternative to the conductive tracks lying against the underside and/or upper side, it may be provided that the components are provided with contact points, of which for example a first provides an electrically conducting contact possibility with respect to the underside, i.e. the lowermost active layer of the component, and another provides an electrically conducting contact possibility with respect to the upper side, i.e. the uppermost active layer of the component. The embroidered conductive tracks are in this case brought into electrically conducting connection with the corresponding contact points.

Electrically conducting contact is preferably brought about by the conductive tracks lying against the corresponding areas. Crimping, clamping, soldering or adhesive bonding is not necessary.

However, the electrical contact may be improved in a further method step. For this purpose, for example, a drop of conductive adhesive or solder may be applied to the contact point.

The conductive tracks run in such a way that conductive tracks which contact the first surface segment and conductive tracks which contact the second surface segment of the same component do not touch one another.

The method allows individual electronic components, for example photovoltaic cells, to be interconnected by means of an embroidering technique. The individual components need not, as previously customary, already be provided with an interconnection and combined into modules before they are applied to the flexible surface structure.

The method steps of (i) embroidering the conductive track, (ii) establishing electrically conducting contact with the first surface segment, for example the underside, of the component and (iii) embroidering further conductive track, which has electrically conducting contact with the second surface segment, for example the upper side, of the component, can be performed repeatedly in full or in part, one conductive track for example connecting the underside of one component to the upper side of a further component in an electrically conducting manner, so that the components are connected in series.

As an alternative or in addition, the first surface segments and the second surface segments, that is to say for example undersides and upper sides, of individual components or of series of components may be respectively connected to one another in an electrically conducting manner, whereby the components or series of components are connected in parallel.

The components may be adhesively attached, screwed, riveted or otherwise fastened onto the flexible surface structure. In a preferred embodiment, the at least one electronic component is applied and fastened by a program-controlled embroidering technique, in particular by means of a shuttle embroidering machine, a multiple-head embroidering machine or some other embroidering machine.

The application and fastening of the at least one electronic component takes place in this case in a process such as that also used, for example, for applying sequins or the like. For this purpose, the components are located on a tape which is unrolled from a reel and fed to the needle for embroidering on. The components may either have at least one opening for passing through the needle, be pierced by the embroidering needle or be embroidered over without being pierced.

The entire process of attachment and establishing contact may consequently take place by a program-controlled embroidering technique.

The embroidering on of the conductive tracks and/or the fastening of the at least one component advantageously takes place by the double-thread system, with an upper thread and a lower thread.

The upper and/or lower threads for embroidering the conductive tracks are electrically conducting. For this purpose, they consist of electrically conducting material or at least contain electrically conducting material. For example, the yarn contains metal filaments. A thread may consist, for example, of a core of PE around which copper or silver has been spun. The yarn may consist of a coated material, it being possible in each case for only the core or the coating to be conductive.

The conductive track may either itself be at least one of the embroidering threads, for example in a double-thread system, or be fastened by means of further embroidering threads, for example in a triple-thread system.

In the latter case, the material for the conductive track neither has to be led through the flexible structure nor applied by means of a needle. There are therefore no special requirements for the flexibility of the conductor, which under some circumstances may compete with the conductivity. A conductive filament or a metal strip may be used, for example, as a conductive track. The embroidering threads may likewise be conductive.

One option is that, when the conductive tracks are embroidered on, the at least one electronic component may also be fastened directly along with them, in which case the thread or threads for the conductive track for establishing contact with the first surface segment, for example the underside, and/or the thread or threads for the conductive track for establishing contact with the second surface segment, for example the upper side, are used for embroidering the component securely in place.

In an advantageous embodiment of the invention, the at least one component is embroidered on in a separate method step by means of nonconducting threads. The separate fastening of the components allows the use of thin, tear-resistant threads and an embroidering procedure that leads to a solid mechanical connection, and in which no allowance has to be made for establishing electrical contact. If the components are lying well against the flexible surface structure, the finished product is unlikely to incur damage that could be caused by components being torn off or bent away. As a result, the product is more robust and more versatile and durable in use.

At the same time, the components are fastened to the flexible surface element in such a way that a good electrically conducting contact with the conductive tracks is always ensured, even when the flexible surface element is folded.

The embroidering procedure is chosen such that on the one hand a component is solidly connected to the underlying surface and the conductive tracks, but on the other hand the upper side of the component is not unnecessarily covered. In particular, the photoactive surface of a solar cell is not unnecessarily impaired. For this purpose, optically transparent threads may also be used.

In modern embroidering machines, a number of conductive tracks and/or electronic components may be embroidered on at the same time. Flexible surface elements may be produced in any widths, for example up to 180 cm, and in virtually any repeat. The embroidering procedure allows any desired arrangements and interconnections of the components. Consequently, circuits can be produced in a tailored form and size.

The electronic components are advantageously applied to the surface structure in a regular pattern, preferably lying approximately against one another. In this case, the surface area offered by the surface structure is optimally utilized. If the components are photovoltaic cells, the efficiency is optimized with respect to the surface area available.

The finished product is distinguished by a mostly covered, but flexible surface.

In a further method step, the electronic component is advantageously coated at least partially with a preferred optically transparent protective layer.

The protective layer provides improved mechanical retention, prevents any projection of the components from the underlying surface and protects the components and conductive tracks from external influences, such as dust and moisture, and from mechanical stress, such as impact and scratching.

At the same time, the protective layer preserves the functional capability of the electrically conducting contacts and prevents the interruption, bridging or other impairment of the embroidered electrically conducting connections.

The protective layer may be applied as a final step to the flexible surface structure, the at least one electronic component located on it and the conductive tracks. The protective layer may, however, also be applied to the component before the component is applied to the surface structure. In this case, the layer must be at least partially removed, for example with a laser, before contact is established, and preferably closed again after contact has been established.

The protective layer may, for example, be rolled on as a film, sprayed on as a setting liquid, applied as a powder or thermally fixed.

As a further method step, it may be provided that the flexible surface structure is heated together with the applied components, for example in an oven or in a running frame. In this case, sintering of the electronic components may take place. The material and/or the contacts are thereby strengthened. The protective layer is subsequently applied.

The object on which the invention is based is further achieved by the use of an embroidering machine for embroidering on at least one conductive track and for applying, fastening and establishing contact for at least one electronic component, in particular a photovoltaic cell, on a flexible surface structure, a first conductive track establishing contact only with a first surface segment, in particular the underside, of at least one component and a second conductive track establishing contact only with a second surface segment, in particular the upper side, of the same at least one component.

Modern embroidering machines allow the creation of complex embroidering paths and the feeding and fastening of flat elements. The thread supply lines, the embroidering needles and the device for feeding the flat elements should be formed in such a way that conducting yarn and electronic components can be processed.

The object is also achieved by a flexible surface structure with at least one electronic component, in particular a photovoltaic cell or a solar module, and at least one electrical conductive track that is embroidered, in particular by the double-thread system, according to the features of claim 10.

According to the invention, a first conductive track establishes contact only with a first surface segment, in particular the underside, of at least one component and a second conductive track establishes contact only with a second surface segment, in particular the upper side, of the same at least one component.

The conductive tracks and/or the at least one component have in this case preferably been attached in a method as described above.

If a number of electronic components are provided, their first and second surface segments, for example undersides and upper sides, may be connected by in each case a common conductive track, whereby a parallel connection is produced. Or one conductive track connects the underside of one component to the upper side of a further component, whereby a series connection is produced.

Combinations of series and parallel connections may likewise be realized.

The surface areas may be formed in such a way as to make good contact with the conductive threads possible. For example, grooves in which the threads run may be provided on the underside and/or on the upper side. For this purpose, the electronic components may, for example, be machined by a laser.

Electrically conducting contact may also be established by way of corresponding contact points which are provided on the electronic component. The contact points may already be formed on the substrate of the electronic component.

The electronic component may be adhesively attached, riveted, screwed or in some other way fastened to the surface structure. In an advantageous embodiment of the invention, the at least one component is embroidered securely in place on the surface structure, in particular by the double-thread system. A thread which at the same time establishes an electrically conducting contact and belongs to a conductive track may be used for the embroidering securely in place. As an alternative, a nonconducting thread may be used.

A nonconducting thread may be led through the component without the electronic properties of the component being impaired, for example without establishing a conducting connection between the underside and the upper side of the component.

A protective layer, which covers at least a second surface segment, in particular the upper side, of the at least one component, is advantageously provided. The protective layer may be attached onto the flexible surface structure over a large surface area, so that components and conductive tracks are effectively protected from external influences. The protective layer is preferably optically transparent.

In an advantageous embodiment of the invention, a multiplicity of components connected in series to one another in an electrically conducting manner are provided, together forming in particular a solar module. The components are in this case predominantly solar cells. Other components for the interconnection of solar cells, for example bypass diodes, may also be integrated in the circuit.

The component preferably has a greatest surface diameter of between 3 mm and 30 mm, in particular greater than 10 mm and up to 25 mm, or in particular of approximately 6 mm.

The component may be a, preferably miniaturized, solar module with at least one solar cell.

The solar module may be partially or completely encapsulated and have an internal interconnection. The electrical terminals are attached such that a connection to a conductive track located or to be attached on the flexible substrate can be established.

The at least one solar cell or solar module is preferably arranged on a platform. The platform may be provided with conductive tracks for connecting and/or interconnecting solar cells and/or solar modules.

The platform may be a substrate onto which the photovoltaically active material is applied, for example by means of a thin-film process. Solar modules on the basis of amorphous or crystalline silicon may also be provided.

The platform may be an electrically insulating auxiliary substrate which does not exceed the dimensions of the actual solar cell or the solar module at all, or not significantly.

The platform may consist of flexible material.

The platform may already be prepared in such a way that possibilities for fastening the component on the flexible structure and/or possibilities for establishing electrical contact on conductive tracks are offered. For this purpose, the platform may, for example, have holes at which it is possible for fastening and/or establishing a contact to be carried out by means of a thread.

The platform may also have conductive regions, for example at the edge of the platform, which are not covered by the solar cell or the solar module. The platform may be provided with contact lugs, which may be flexible, for example consist of fabric or film, and by way of which electrical contact with a conductive track can be established.

The platform with the solar cells and conductive tracks located on it may be partially or completely encapsulated. An encapsulating material protects the component from environmental influences. It is preferably insulating and optically transparent.

It may be provided that only certain regions, for example where a solar cell or a solar module is provided, are covered by encapsulating material. It is also possible for the entire upper side of the platform on which solar cells, solar modules and/or conductive tracks are attached to be encapsulated. Or the entire platform is encapsulated.

Regions that are intended for establishing electrical contact, for example by means of embroidering, sewing, adhesive bonding or soldering, may be excepted from the encapsulation.

A miniaturized solar module may be produced by applying conductive tracks and solar cells to a platform and at least partially encapsulating them.

The object is also achieved by a solar module comprising a multiplicity of solar cells or solar modules connected to one another in an electrically conducting manner, the solar cells in each case being embroidered on a flexible surface structure. The attachment of the solar cells and establishment of an electrically conducting contact for them takes place in particular in a method as described above.

The individual fastening of the solar cells on the support material by means of an embroidering technique allows a flexible choice of arrangements of the individual cells and dimensions of the module.

If the support material is a flexible surface structure, the solar module can be folded and rolled up. The solar module is then versatile in use and easily transportable.

The invention is explained below in exemplary embodiments on the basis of drawings.

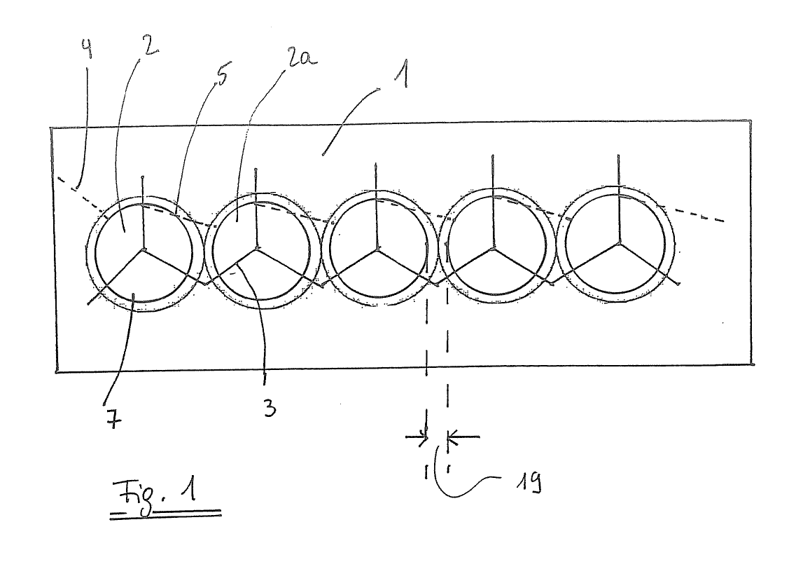

FIG. 1 schematically shows a plan view of a first example of a flexible surface structure with components connected in series;

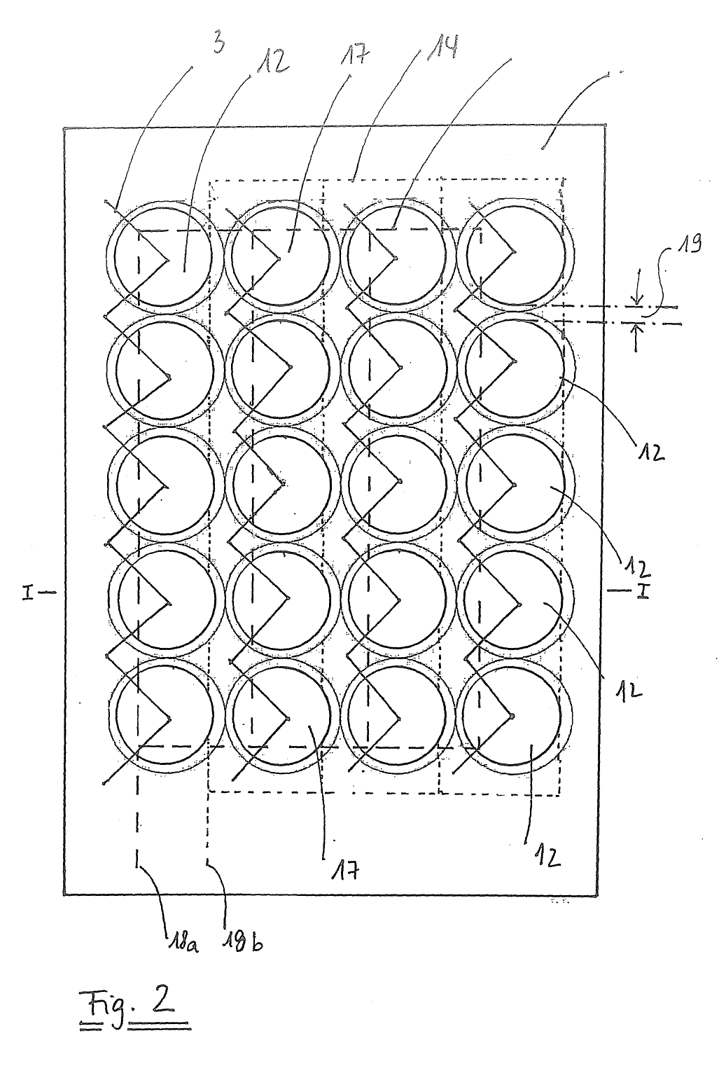

FIG. 2 schematically shows a plan view of a second example of a flexible surface structure with components connected in parallel;

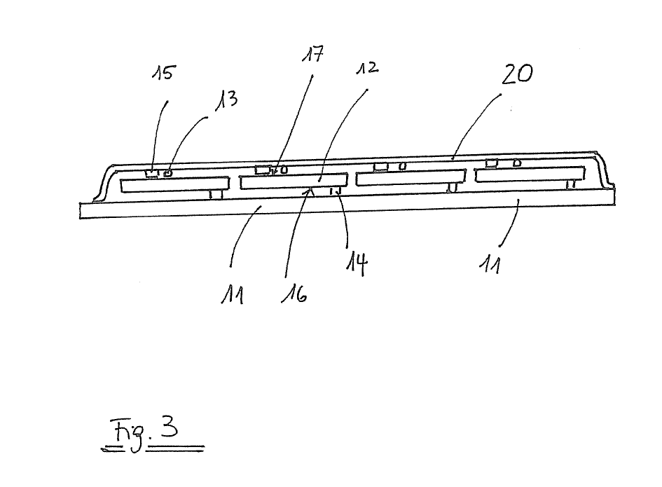

FIG. 3 schematically shows a sectional diagram of FIG. 2 along the line I-I;

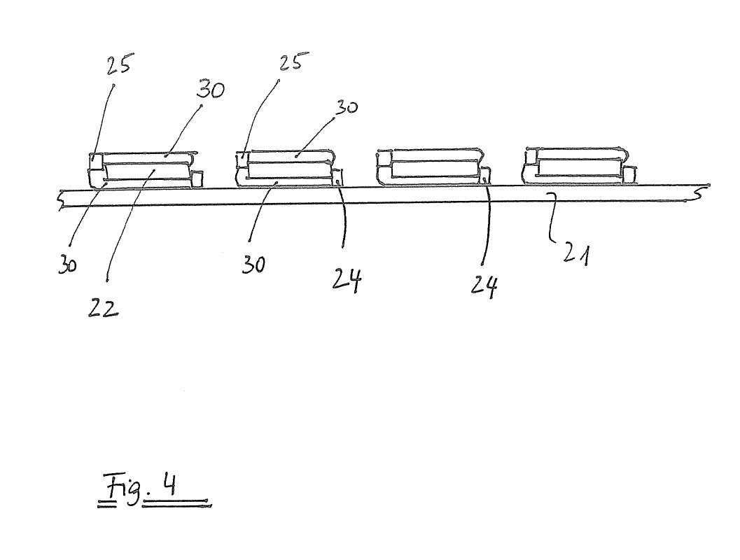

FIG. 4 schematically shows the sectional view of a third example of a flexible surface structure with coated components;

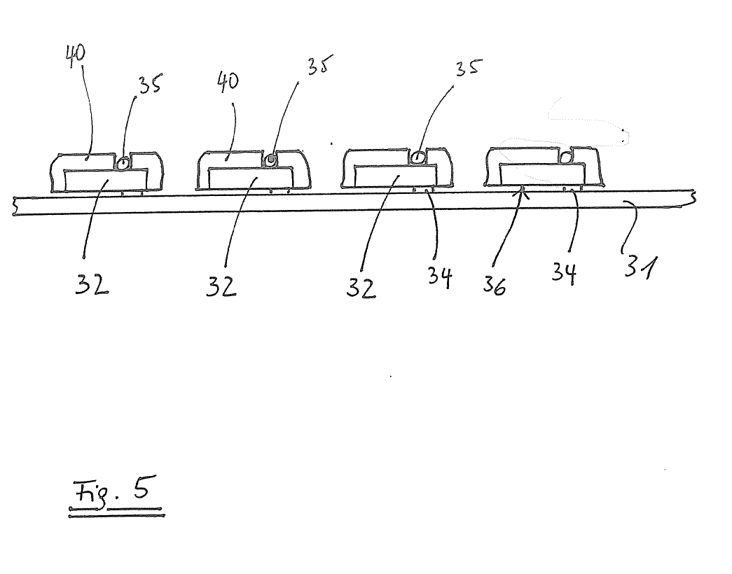

FIG. 5 schematically shows the sectional view of a fourth example of a flexible surface structure with coated components;

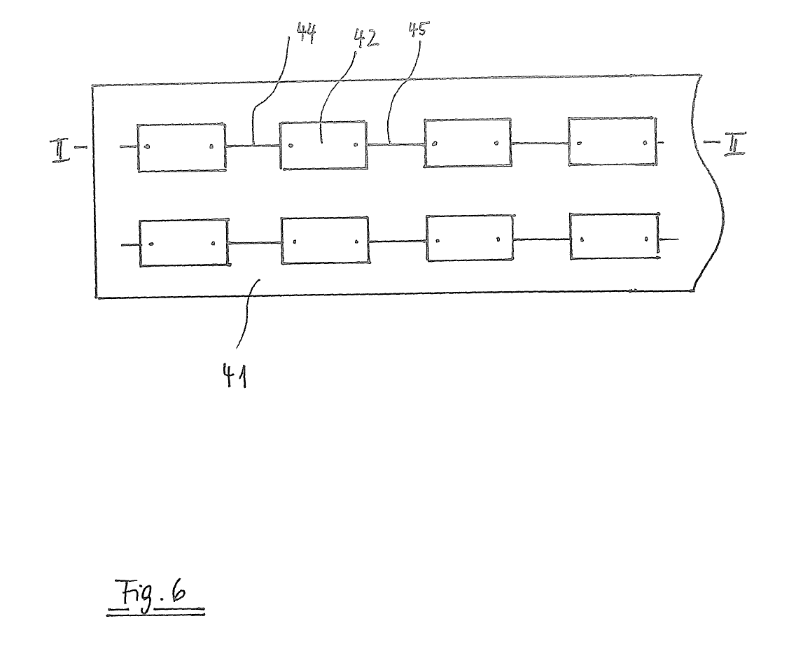

FIG. 6 schematically shows a plan view of a fifth example of a flexible surface structure with components connected in series;

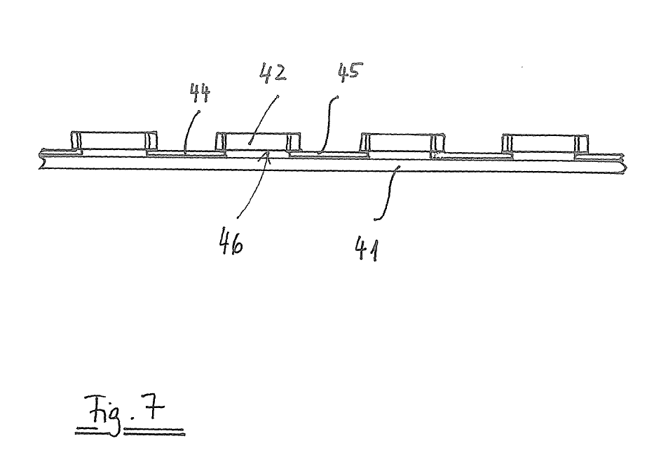

FIG. 7 schematically shows a sectional diagram of FIG. 6 along the line II-II;

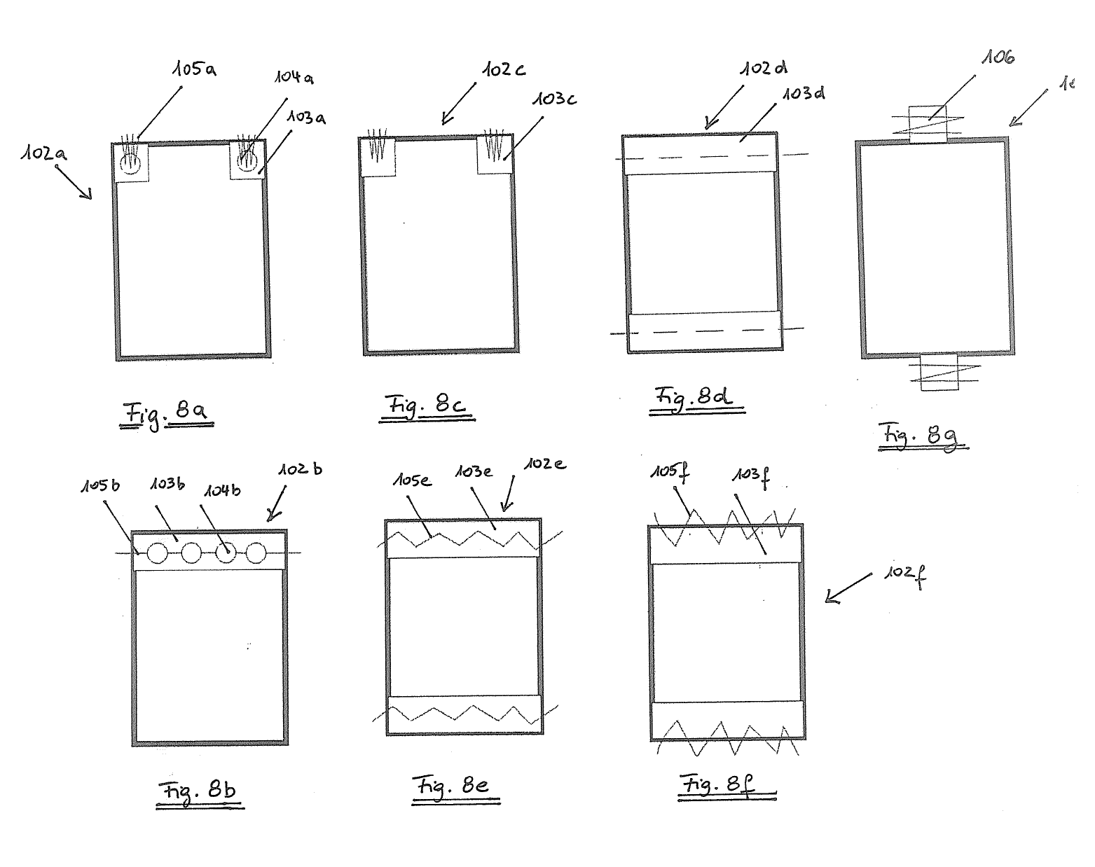

FIGS. 8a-8g schematically show various possibilities for fastening solar modules on flexible surface structures.

FIG. 1 schematically shows a flexible surface structure 1, which is loaded with electronic components 2. In the example shown, the components 2 are embroidered securely in place on the flexible circuit structure 1 by a nonconducting thread 3. Provided for each component 2 is a conductive track 4, which establishes an electrically conducting contact with the underside, not shown any more precisely in the drawing, of the component 2 and a further conductive track 5, which establishes an electrical conducting contact with the upper side 7 of the component 2.

The embroidery pattern is chosen such that the conductive track connects the upper side 7 of a component 2 to the underside (not shown) of a neighboring component 2a.

The components 2 are arranged with a spacing 19.

FIG. 2 shows, likewise schematically, a flexible surface structure 11, which is loaded with electronic components 12. In this example too, the electronic components 12 are embroidered securely in place by a nonconducting thread 13. A first conductive track 14 connects all the undersides (not shown in the figure) of the components 12; a further conductive track 15 connects the upper sides 17 of the components 12. In this way, the components 12 are arranged in a parallel connection.

The ends 18a, 18b of the conductive tracks 13, 14 may be configured such that they can be tapped from the outside, for example by way of a clamp or a connector not shown in the figure.

The entire arrangement is coated with a protective layer 20 that is not represented in this figure.

As an alternative, series of components, as shown for example in FIG. 21, may also be connected in parallel.

FIG. 3 schematically shows a sectional diagram of FIG. 2 along a sectional line I-I. Contact is established with the undersides 16, facing the flexible surface structure 11, of the electronic components 12 by a first conductive track 14 and with the upper sides 17, facing away from the flexible surface structure 11, of the electronic components 12 by a second conduction part 15. The electronic components 12 are fastened to the flexible surface structure by a nonconducting thread 13.

The entire arrangement is coated with a protective layer 20. The electronic components 12 are preferably photovoltaic cells on the basis of CIS, CIGS, CIGSS, CdTe, CdS, TiO2, a-Si:H, SiGE, GaAs, GaInP, GaInAs or other semiconductors and semiconductor compounds. They preferably have a greatest surface diameter of between 3 mm and 10 mm, more preferably of approximately 6 mm.

The conducting threads 13 consist of conducting, partially conducting or nonconducting material and may be coated or spun with conducting material.

Any material that can be pierced by an embroidering needle may be used as the flexible surface structure 11.

The protective layer 20 consists, for example, of a polymer, of a glass or of Teflon.

A thin protective layer 20 of a polyester or a polyamide may be applied, for example in a foulard. The entire arrangement remains flexible, even with a protective layer 20.

The embroidering takes place with a back stitch, a turning stitch, a flat stitch, a braiding or some other type of embroidery.

FIG. 4 schematically shows the sectional view of a third example of a flexible surface structure 21 with coated components 22. The components 22 have in each case been coated completely with a protective layer 30, and consequently encapsulated, before application. For establishing contact, the protective layer 30 must be removed at least two contact points at which the first conductive track 24 and the second conductive track 24 lie. For this purpose, the protective layer 30 may, for example, be etched away or removed by a laser, preferably before application.

FIG. 5 schematically shows the sectional view of a third example of a flexible surface structure 31 with coated components 32. The components 32 are already arranged on an underlying surface, for example on an adhesive roll, before application. On this, the components 32 may be coated with a protective layer 40, so that the underside 36 of the components 32 remains uncoated and can have contact established with a first conductive track 34. Before contact is established with the second conductive track 35, the protective layer 40 must be removed at the contact point. This may take place, for example with a laser, when the components 32 have already been applied to the textile surface structure 32.

FIG. 6 schematically shows a plan view of a fifth example of a flexible surface structure 41 with components 42 connected in series. FIG. 7 schematically shows a sectional diagram of FIG. 6 along the line II-II.

In this example, the components 42 are configured such that the contact points are located on the underside 46 of the components 42.

A first conductive track 44 establishes contact for the component 42 on a first surface segment, which is located on the underside 46 of the component 42. A second conductive track 45 establishes contact with a second surface segment of the same component 42, which is likewise located on the underside 46 of the component 42.

Electrical contact is established by means of a conducting connection by an embroidering technique. The components 42 may be additionally over-embroidered with nonconducting securing threads that are not explicitly shown in the figure.

FIGS. 8a-8g schematically show various possibilities for fastening solar modules 102a, 102b, 102c, 102d, 102e, 102f, 102g on flexible surface structures 101.

In FIGS. 8a and 8b, the solar modules 102a and 102b have contact regions 103a, 103b, provided on one side, with holes 104a, 104b. These can be used for an embroidery connection, for example by means of a conductive thread 105a, 105b.

The solar modules 102c, 102d, 102e and 102f shown in FIGS. 8c, 8d, 8e and 8f likewise have contact regions 103c, 103d, 103e and 103f, but without holes. The contact regions 103c, 103d, 103e and 103f must be pierced for fixing with a thread.

The contact regions 103a, 103b, 103c shown in FIGS. 8a-8c are arranged at an edge of the solar module 102a, 102b, 102c. If the fixing takes place exclusively by way of the contact regions 103a, 103b, 103c, the fixed solar modules 102a, 102b, 102c are attached onto the flexible surface structure in an imbricated manner. In this case, there is no surface-area connection between the solar modules 102a, 102b, 102c and the flexible surface structure, which contributes to better draping qualities of the flexible surface structure provided with solar modules.

A conductive embroidering thread 105e, 105f may, as shown for example in FIGS. 8e and 8f, be taken back and forth in a zigzagging manner, in order to achieve a larger contact area.

The solar module 101g shown in FIG. 8g has two contact lugs 106, which are produced from conductive fabric or conductive film.

1-18. (canceled)

19. A method for attaching a flat electronic component to a surface of a flexible structure and for establishing electrical contact between said electronic component and said surface, said method comprising steps of
(i) applying a first conductive track to said surface
(ii) establishing an electrical contact between said track and a first surface segment of said electronic component, and
(iii) applying a second conductive track to said surface establishing an electrical contact between said track an a second surface segment of said electronic component,
wherein at least one conductive track is applied by embroidering it to said flexible structure.

20. The method as claimed in claim 19, wherein the flat electronic component is a photovoltaic cell or a solar module.

21. The method as claimed in claim 19, wherein the first surface segment is an underside of the electronic component and the second surface segment is an upper side of the same electronic component.

22. The method as claimed in claim 19, wherein at least one conductive track is embroidered on by a program-controlled embroidering technique.

23. The method as claimed in claim 19, wherein the electronic component is applied and fastened by a program-controlled embroidering technique.

24. The method as claimed in claim 19, further comprising a step in which the component is embroidered on by means of nonconducting threads.

25. The method as claimed in claim 19, further comprising a step in which the component is adhesively attached.

26. The method as claimed in claim 19, further comprising a step in which the electronic component is at least partially coated with an optically transparent protective layer.

27. The method as claimed in claim 26, wherein the protective layer is applied to the electronic component and at least partially removed again before electrical contact is established.

28. The method as claimed in claim 26, wherein the protective layer is applied as a film to the surface structure and the electronic component applied thereto.

29. The method as claimed in claim 28, wherein the protective layer is rolled on or sprayed on as a setting liquid.

30. The method as claimed in claim 19, wherein the electronic components are applied to the surface structure in a regular pattern.

31. A method for embroidering on at least one conductive track and for applying, fastening and establishing contact for at least one electronic component on a flexible surface structure, at least one first conductive track establishing contact only with a first surface segment, of the component, and at least one second conductive track establishing contact only with a second surface segment of the same component wherein an embroidering machine is used.

32. The method as claimed in claim 31, wherein a shuttle embroidering machine is used.

33. A flexible structure having a least one electronic component, and having embroidered conductive track, wherein a first conductive track contacts only a first surface segment of the component and a second conductive track contacts only a second surface segment of the component.

34. The flexible surface structure as claimed in claim 33, wherein at least one electronic component is a photovoltaic cell or a solar module,

35. The flexible surface structure as claimed in claim 33, wherein at least one electrical conductive track is embroidered by the double-thread system.

36. The flexible surface structure as claimed in claim 33, wherein the first surface segment is the underside of the component and the second surface segment is the upper side of the same component.

37. The flexible surface structure as claimed in claim 33, wherein the at least one component is embroidered securely in place on the surface structure.

38. The flexible surface structure as claimed in claim 37, wherein at least one component is embroidered securely in place by the double-thread system.

39. The flexible surface structure as claimed in claim 33, wherein a protective layer, which covers at least the second surface segment of the at least one component is provided.

40. The flexible surface structure as claimed in claim 33, wherein a multiplicity of components connected in series to one another in an electrically conducting manner are provided.

41. The flexible surface structure as claimed in claim 40, wherein a multiplicity of components together form at least one solar module

42. The flexible surface structure as claimed in claim 33, wherein the conductive track contains silver or copper threads.

43. The flexible surface structure as claimed in claim 33, wherein the at least one component is over-embroidered and/or embroidered on by means of nonconducting threads.

44. The flexible surface structure as claimed in claim 33, wherein the at least one component is adhesively attached.

45. The flexible surface structure as claimed in claim 33, wherein the at least one component has a greatest surface diameter of between 3 mm and 30 mm.

46. A solar module comprising a multiplicity of solar cells or solar modules connected to one another in an electrically conducting manner, wherein the solar cells or solar modules are in each case embroidered on a support material.

47. A solar module as claimed in claim 46, wherein the support material is a flexible surface structure.

48. A solar module as claimed in claim 46, wherein the solar cells or solar modules are in each case embroidered in a method according to claim 37.

49. A solar module as claimed in claim 46, wherein each said solar cell or solar module is attached to said support material by steps of
(i) applying a first conductive track to said surface,
(ii) establishing an electrical contact between said track and a first surface segment of said electronic component, and
(iii) applying a second conductive track to said surface establishing an electrical contact between said track and a second surface segment of said electronic component,
wherein at least one conductive track is applied by embroidering it to said flexible structure.
